(19) United States
(12) Patent Application Publication
(10) Pub. No.: US 2010/0330938 A1
(43) Pub. Date: Dec. 30, 2010

(54) POWER DETECTOR

(75) Inventor: Yi Yin, Munich (DE)

Correspondence Address: LARSON NEWMAN & ABEL, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 12/918,168

(22) PCT Filed: Mar. 13, 2008
(86) PCT No.: PCT/IB2008/050921

§ 371 Date: Aug. 18, 2010

(51) Int. Cl. H04B 1/04; H03F 3/45

(52) U.S. Cl. 455/127.1; 330/257

(57) ABSTRACT

A power detector comprises a pair of transistor amplifier elements having respective control terminals for receiving with opposite polarities a radio/mm-wave frequency signal whose power is to be detected. Respective alternately-conductive parallel amplifier paths are controlled by the control terminals. A low pass filter and current mirror is responsive to the combined currents flowing in the parallel amplifier paths for producing a low pass filtered signal. A detector output stage is responsive to the low pass filtered signal. Each of the pair of amplifier elements includes a respective impedance through which flows current from the respective amplifier path and current from the respective control terminal.

### FIELD OF THE INVENTION

This invention relates to a power detector, to an amplifier apparatus and to a radio communication apparatus.

### BACKGROUND OF THE INVENTION

Power detectors can be used to monitor and control the output of power amplifiers. Power amplifiers are used in communication transmitter chips, to amplify and transmit Radio Frequency and/or mm-Wave frequency signals. These signals must be transmitted at a prescribed power level. More specifically, power detectors may be used to provide dynamic bias control for an amplifier and to mitigate the impact of process, voltage and temperature variations, to provide a built-in self-compensation mechanism and to guarantee the output power at an antenna to ensure conformity with the communication regulations. Power detectors for use in high radio frequency (‘RF’) and millimeter -wave (‘mm-wave’) frequencies present some specific design features.

The article by V. Leung, L. Larson, and P. Gudem, “Digital-IF WCDMA handset transmitter IC in 0.25-um SiGe BiCMOS,” in IEEE Journal of Solid-State Circuits, vol. 39, no. 12, pp. 2215-2225, December 2004 describes a power detector circuit for RF frequencies in which power detection is accomplished by two bipolar devices Q₁, Q₂ configured as common emitter amplifiers. They are biased with low quiescent current I_{cq}, and their collector currents are clipped during large-signal conditions. As a result, their average (DC) collector currents are raised above the quiescent level. The extra DC current, which is proportional to the input power, is mirrored by field effect transistors (‘FET’) M₁ and M₂ and multiplied by a transistor pair Q₃, Q₄ and, with a digitally programmable ratio, by a pair of FETs M₃ and M₄. The detector output extra DC current ΔI_{cq} is applied to supplement the fixed quiescent current of a cascode amplifier bias network to control the amplifier power output.

The paper by U. Pfeiffer, “A 20 dBm Fully-Integrated 60 GHz SiGe Power Amplifier with Automatic Level Control,” presented at the European Solid-State Circuits Conference, pp. 356-359 September 2006 describes a similar power detection circuit for use at higher, mm-wave frequencies, with a digital-to-analog converter (‘DAC’) and comparator circuit for digitization that can be used in a software controlled successive approximation to read out the delivered power level via the chip's serial digital interface and used to control the amplifier power output.

### SUMMARY OF THE INVENTION

The present invention provides a power detector, an amplifier apparatus and a radio communication apparatus as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. Elements in the figures are illustrated for simplicity and clarity and have not necessarily been drawn to scale.

FIG. 1 is a schematic diagram of an example of a transmitter module including a power amplifier, a power detector and an antenna.

FIG. 2 is a schematic diagram of a known power detector, and

FIG. 3 is a schematic diagram of an embodiment of a power detector in accordance with the present invention.

### DETAILED DESCRIPTION OF THE PREFERRED EMBODIMENTS

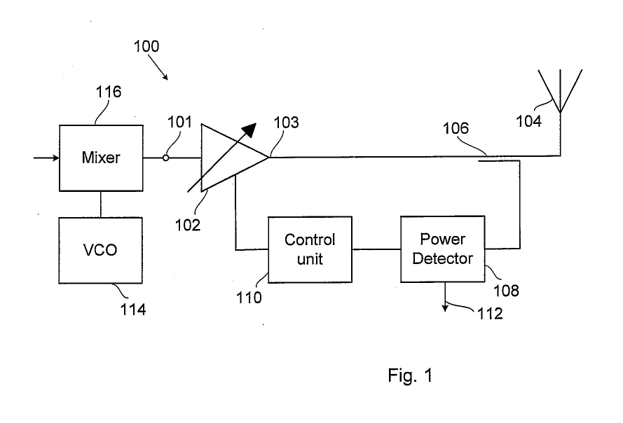

The example of a radio communication apparatus shown in FIG. 1, is a transmitter module 100 which comprises a variable gain power amplifier 102. The variable gain power amplifier 102 has an input 101 at which an input signal can be presented and an output 103 at which an amplified signal can be outputted. The amplified signal has a signal power proportional to the signal power of the input signal. The transmitter module 100 further includes an antenna 104 for broadcasting the amplified signal, a coupler for extracting a signal representative of the power of the amplified signal from the amplifier output 103, a power detector 108 for producing a detector signal proportional to the power of the signal from the coupler and a control unit 110 for producing a control signal for controlling operating parameters of the amplifier 102, including bias voltages for the amplifier, so as to control the gain of the amplifier dynamically. An output 112 is provided, which can be used to enable performance characterisation of the amplifier 102, that is to say for an operator to make an external measurement of the amplifier power in different operating conditions using the power detector 108. The output 112 may also be used to control inputs for the power amplifier 102, for example by controlling the signal level of local oscillators.

The shown embodiment may for example used for radio frequency & mm-wave frequency ranges and the power detector may be a power detector for radio frequency & mm-wave frequency ranges having low power consumption and highly linear, low temperature sensitivity. For example, in one application, for use in the automotive industry at a frequency of 77 GHz, the performance characterisation and potential for power control can keep power constant to within 13-15 dBm over a range of ambient temperatures from −40° C. to +125° C. in spite of other environmental variations and with low component cost.

In one implementation, the amplifier 102, power detector 108 and processor 110 are located in a single integrated circuit manufactured using SiGe-BiCMOS technology, which offers cost-savings compared with GaAs technology. In other implementations they are located in two or more separate circuits. The signal at the input 101 may be generated using a voltage controlled oscillator 114 and a mixer 116, for example, as shown.

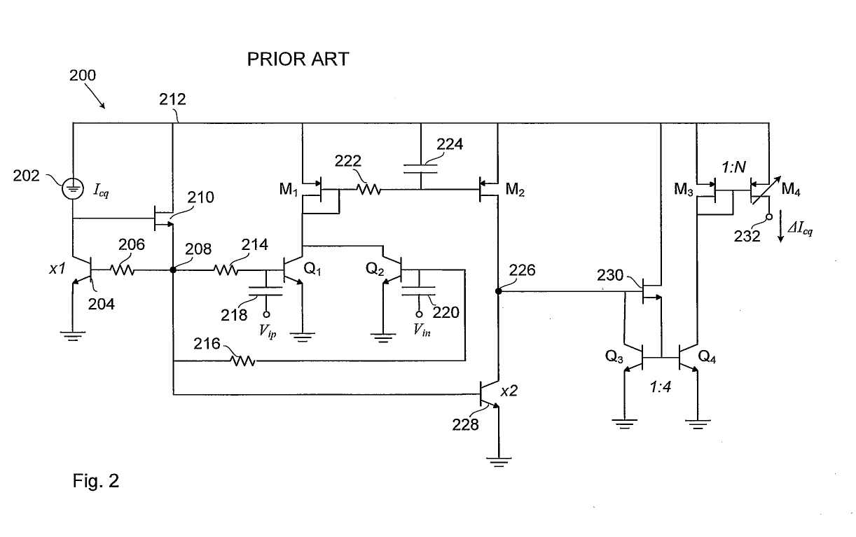

FIG. 2 shows a power detector 200 described in the article by V. Leung, L. Larson, and P. Gudem, “Digital-IF WCDMA handset transmitter IC in 0.25-um SiGe BiCMOS,” in IEEE Journal of Solid-State Circuits, vol. 39, no. 12, pp. 2215-2225, December 2004. The power detector of present FIG. 2 comprises two bipolar transistors Q₁, Q₂ configured as common emitter amplifiers. A bias circuit includes a current source 202, which supplies a quiescent current level I_{cq} from a supply rail 212 to the collector of a bipolar transistor 204 whose emitter is connected to ground and whose base is connected through a resistor 206 to a bias node 208, and an n-type field-effect transistor (‘FET’) 210 having its source connected to the node 208, its drain connected to the supply rail 212 and its gate connected to the collector of the transistor 204 so as to maintain the node 208 at a desired bias voltage. In one implementation, the current source is a resistor of suitable value. The bias node 208 is connected through resistors 214 and 216 to the bases of the transistors Q₁ and Q₂, respectively, so as to maintain the bases of the transistors at suitable quiescent voltages and supply suitable quiescent currents to the base-emitter junctions of the transistors. RF anti-phase voltages Vᵢₚ and Vᵢₙ representative of the output of the amplifier 102 are applied from a coupler such as the coupler 106 of FIG. 1 through respective capacitors 218 and 220 to the bases of the transistors Q₁ and Q₂. The emitters of the transistors Q₁ and Q₂ are connected to ground and their collectors are connected together to the drain of a p-type FET M₁ whose source is connected to the rail 212 and which is connected in a low-pass filter and current mirror configuration with a p-type FET M₂. The gate of the FET M₁ is connected to its drain and the gates of the FETs M₁ and M₂ are connected together through a resistor 222, the gate of the FET M₂ being connected through a capacitor 224 to the rail 212. The source of the FET M₂ is connected to the supply rail 212 and its drain is connected to a node 226 which is connected to the collector of a bipolar transistor 228, whose emitter is connected to ground and whose base is connected directly to the bias node 208 so as to pass a base-emitter quiescent current of twice the level of those of the transistors 204, Q₁ and Q₂.

A current multiplier pair of bipolar transistors Q₃ and Q₄ have their emitters connected to ground and their bases connected to each other and to the source of an n-type FET 230, whose drain is connected to the supply rail 212 and whose gate is connected to the node 226 and to the collector of the transistor Q₃. The collector of the transistor Q₄ is connected to supply current to a pair of p-type FETs M₃ and M₄ connected in current mirror configuration with a digitally programmable multiplication ratio. More specifically, the sources of the FETs M₃ and M₄ are connected to the supply rail 212, the drain of the FET M₃ is connected to the collector of the transistor Q₄ and the gates of the FETs M₃ and M₄ are connected together and to the drain of the FET M₃. The drain of the FET M₄ supplies a current ΔI_{cq} to an output terminal 232.

In operation, the voltage drop in the transistor 204 due to its collector current I_{cq} is applied to the gate of the FET 210 and causes the FET 210 to pull the voltage at the bias node 208 up towards the voltage of the supply rail 212 until the increased conductance of the transistor 204 stabilises the bias voltage at the desired level. The bipolar transistors Q₁, Q₂ are biased with low quiescent current I_{cq} to operate in class B or class AB conditions. During large-signal conditions, device Q₁ and Q₂ are shut off alternately during half or less than half of every cycle. Therefore, the drain current of Q₁ varies approximately sinusoidally for one half-cycle, while the drain current of Q₂ is zero and conversely during the other half-cycle. The rectified currents combine together at the collectors of the transistors Q₁, Q₂, and charge the capacitor 224 through the resistor 222. As a result, the DC drain current I of M2 is raised above the quiescent level with a constant level which is exponentially related to the saturation current Iₛ (I=Iₛ*EXP(Vᵢₚ,Vᵢₙ/V_{T}) , where Vᵢₚ and Vᵢₙ are the peak amplitudes of the input base-emitter voltage applied to the transistors Q₁, Q₂, and V_{T} is the threshold voltage of the transistors. The quiescent current of the transistor 228 is equal to the quiescent current corresponding to those of the transistors Q₁, Q₂. Therefore, only extra DC current ΔI_{cq} flows in the collector of the transistor Q3. The current is amplified by Q4 and multiplied further with a digitally programmable ratio by a pair of FETs M₃ and M₄ to provide the detector output extra DC current ΔI_{cq} at the output terminal 232.

The prior power detector shown in FIG. 2 has several disadvantages. For example, although the transistor pair Q₁, Q₂ is biased with low quiescent current, in practice large input signals cause their average (DC) collector to be raised exponentially above the quiescent level, increasing the power consumption of the power detector. Also, the linearity of the power detector (ΔI_{cq} versus input signal amplitude) is insufficient for some applications due to the non-linear transconductance gm (current versus voltage) of the transistor pair Q₁, Q₂. Furthermore, in order to keep each of the FETs working in the saturation region with relatively small override voltages even under large-signal conditions, the width of each FET transistor should be large enough, which penalises big chip area. Moreover, this power detector has relatively large temperature sensitivity, which is insufficient for some applications.

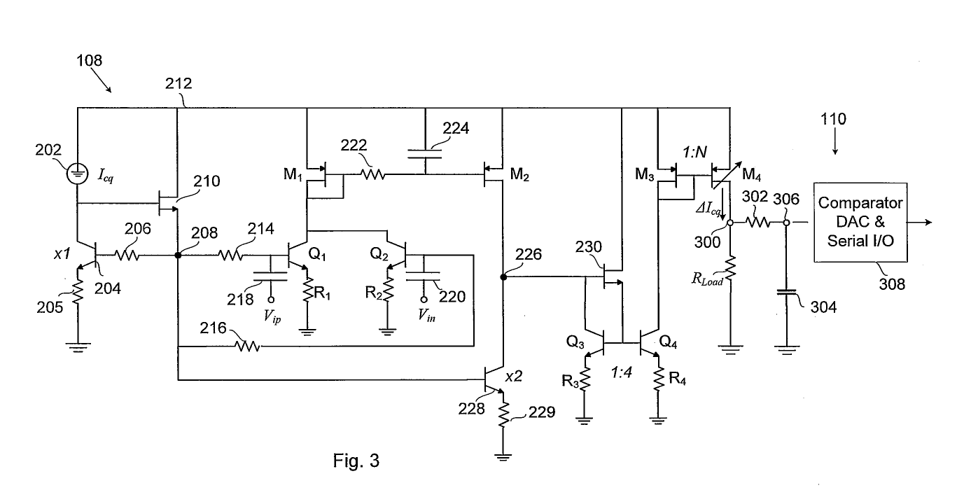

FIG. 3 shows by way of example an embodiment of the present invention which can be designed to avoid some or all of the disadvantages of the power detector of FIG. 2. In FIG. 3, the elements bear the same references as similar elements of FIG. 2, even if their size or value may be different.

The power detector of FIG. 3 comprises a pair of class B biased common emitter transistors Q₁ and Q₂, current mirrors and multipliers M₁, M₂ and M₃, M₄. The transistors Q₁ and Q₂ have emitter-degeneration resistors R₁, R₂, with emitter-degeneration resistors R₃, R₄ for the transistors Q₃ and Q₄ and emitter-degeneration resistors 205 and 229 for the biasing transistors 204 and 228 and an on-chip resistance R_{Load} in series with the FET M₄ drain between a node 300 and ground, to convert the output current ΔI_{cq} to voltage. A further low pass filter is provided, comprising a resistor 302 in series between the node 300 and an output terminal 306 and a shunt capacitor 304 connected between the output terminal 232 and ground, as shown in FIG. 3.

More specifically, the emitter-degeneration resistors R₁, R₂ are of value R_{E} and are connected between ground and the emitters of the respective ones of the transistors Q₁ and Q₂. The emitter-degeneration resistor 205 for the biasing transistor 204 is also of value, the emitter-degeneration resistors 229 and R₃ at the emitters of transistors 228 and Q₃ are of value ½ R_{E}, and the emitter-degeneration resistor R₄ at the emitter of transistor Q₄ is of value ¼ R_{E}. Accordingly, each of the pair of transistors Q₁ and Q₂ forms an amplifier element which includes a respective impedance, the respective emitter-degeneration resistor R₁, R₂, through which flows current in the respective collector-emitter path (the amplifier path of the transistor) and current in the respective control terminal (the base of the transistor). For large signal operation of the bipolar transistors Q₁ and Q₂, the added emitter-degeneration resistors R₁, R₂ increase the input impedance, so that the base current and therefore the collector current of each transistor is substantially reduced. In this case, power consumption is reduced correspondingly . Quiescent voltage is maintained by similar emitter-degeneration resistors 229 and R₃ of value R_{E} for the biasing transistors 204 and 228 and which contribute to further reduction in power consumption. Bipolar transistors (notably Q₁ and Q₂) in this circuit have a negative temperature coefficient, whereas the emitter-degeneration resistors have a positive temperature coefficient, thus providing a degree of temperature compensation of the output.

The current mirrors and multipliers M₁, M₂ and M₃, M₄ can utilize smaller width MOS FETs than in the power detector of FIG. 2 without impacting override voltage. With the emitter-degeneration resistors of FIG. 3, the transconductance is approximately equal to 1/R_{E}, which is less dependent on the amplitude of large input signals, so the linearity of the current mirrors and multipliers M₁, M₂ and M₃, M₄ is also improved.

For RF and mm-wave frequency application, the additional low-pass filter comprising the resistor 302 and the capacitor 304 facilitates removing other residual harmonics coupling into the DC output from adjacent parts of the transmitter module.

The analogue output signal at the terminal 306 may be utilized directly or may be converted to a digital signal using a comparator, digital-to-analogue converter and serial input/output 306, as shown in FIG. 3, and the output converter 308 may be introduced in the control unit 110 of FIG. 1.

In the foregoing specification, the invention has been described with reference to specific examples of embodiments of the invention. It will, however, be evident that various modifications and changes may be made therein without departing from the broader spirit and scope of the invention as set forth in the appended claims. For example, the connections may be a type of connection suitable to transfer signals from or to the respective nodes, units or devices, for example via intermediate devices. Accordingly, unless implied or stated otherwise the connections may for example be direct connections or indirect connections.

The semiconductor material described herein can be other semiconductor material or combinations of materials than those specifically described by way of example, such as gallium arsenide, silicon germanium, silicon-on-insulator (SOI), silicon, monocrystalline silicon, the like, and combinations of the above.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans will appreciate that conductivity types and polarities of potentials may be reversed.

Some of the above embodiments, as applicable, may be implemented using a variety of different information processing systems. For example, although FIG. 1 and the discussion thereof describe an exemplary information processing architecture, this exemplary architecture is presented merely to provide a useful reference in discussing various aspects of the invention. Of course, the description of the architecture has been simplified for purposes of discussion, and it is just one of many different types of appropriate architectures that may be used in accordance with the invention. Those skilled in the art will recognize that the boundaries between logic blocks are merely illustrative and that alternative embodiments may merge logic blocks or circuit elements or impose an alternate decomposition of functionality upon various logic blocks or circuit elements.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “operably connected,” or “operably coupled,” to each other to achieve the desired functionality.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage.

1. A power detector comprising:
a pair of transistor amplifier elements having respective control terminals for receiving with opposite polarities a radio/mm-wave frequency signal whose power is to be detected and respective alternately-conductive parallel amplifier paths controlled by said control terminals;
a low pass filter and current mirror responsive to combined currents flowing in said parallel amplifier paths for producing a low pass filtered signal; and
a detector output stage responsive to said low pass filtered signal;
a respective impedance connected in series with the respective amplifier path between each of the amplifier elements of said pair and a source of bias voltage (ground) and through which flows current from the respective amplifier path and current from the respective control terminal.

2. A power detector as claimed in claim 1, wherein said detector output stage includes a further low pass filter.

3. A power detector as claimed in claim 1, wherein said transistor amplifier elements of said pair are bipolar transistors and said respective impedances comprise emitter-degeneration impedances.

4. A power detector as claimed in claim 3, wherein said pair of amplifier elements is connected in common-emitter configuration.

5. A power detector as claimed in claim 4, wherein said pair of amplifier elements is arranged to amplify said combined currents in class B or class AB conditions.

6. Amplifier apparatus comprising an amplifier having an amplifier output and a power detector as claimed in claim 1, which is responsive to a power of a signal at said amplifier output.

7. Radio communication apparatus comprising amplifier apparatus as claimed in claim 6, and an antenna connected operationally with said amplifier output.

8. A power detector as claimed in claim 2, wherein said transistor amplifier elements of said pair are bipolar transistors and said respective impedances comprise emitter-degeneration impedances.

9. Amplifier apparatus comprising an amplifier having an amplifier output and a power detector as claimed in claim 2, which is responsive to a power of a signal at said amplifier output.

10. Amplifier apparatus comprising an amplifier having an amplifier output and a power detector as claimed in claim 3, which is responsive to a power of a signal at said amplifier output.

11. Amplifier apparatus comprising an amplifier having an amplifier output and a power detector as claimed in claim 4, which is responsive to a power of a signal at said amplifier output.

12. Amplifier apparatus comprising an amplifier having an amplifier output and a power detector as claimed in claim 5, which is responsive to a power of a signal at said amplifier output.

13. Amplifier apparatus comprising an amplifier having an amplifier output and a power detector as claimed in claim 8, which is responsive to a power of a signal at said amplifier output.

14. Radio communication apparatus comprising amplifier apparatus as claimed in claim 9, and an antenna connected operationally with said amplifier output.

15. Radio communication apparatus comprising amplifier apparatus as claimed in claim 10, and an antenna connected operationally with said amplifier output.

16. Radio communication apparatus comprising amplifier apparatus as claimed in claim 11, and an antenna connected operationally with said amplifier output.

17. Radio communication apparatus comprising amplifier apparatus as claimed in claim 12, and an antenna connected operationally with said amplifier output.

18. Radio communication apparatus comprising amplifier apparatus as claimed in claim 13, and an antenna connected operationally with said amplifier output.
